(19) United States
(12) Patent Application Publication
(10) Pub. No.: US 2011/0133216 A1
(43) Pub. Date: Jun. 9, 2011

(54) METHOD OF MANUFACTURING SEMICONDUCTOR LIGHT EMITTING DEVICE AND STACKED STRUCTURE BODY

(75) Inventor: Yasuharu SUGAWARA, Kanagawa-Ken (JP)

(73) Assignee: Kabushiki Kaisha Toshiba, Tokyo (JP)

(21) Appl. No.: 12/876,007

(22) Filed: Sep. 3, 2010

(30) Foreign Application Priority Data
Dec. 9, 2009 (JP) 2009-279284

(51) Int. Cl. H01L 33/08; H01L 33/00

(52) U.S. Cl. 257/88; 438/28; 257/E33.001

(57) ABSTRACT

According to one embodiment, a method is disclosed for manufacturing a semiconductor light emitting device. The method can include forming a plurality of semiconductor stacked bodies on a first major surface of a support substrate with a gap between two neighboring semiconductor stacked bodies. The semiconductor stacked bodies includes a first semiconductor layer, a second semiconductor layer, and a light emitting layer provided between the first semiconductor layer and the second semiconductor layer. The method can bond the plurality of semiconductor stacked bodies to one other support substrate with a bonding member. In addition, the method can remove the support substrate from the plurality of semiconductor stacked bodies by irradiating the plurality of semiconductor stacked bodies with a laser light from a second major surface of the support substrate on a side opposite to the first major substrate. The bonding member is not irradiated with the laser light.

### CROSS-REFERENCE TO RELATED APPLICATIONS

This application is based upon and claims the benefit of priority from the prior Japanese Patent Application No. 2009-279284, filed on Dec. 9, 2009; the entire contents of which are incorporated herein by reference.

### FIELD

Embodiments described herein relate generally to a method of manufacturing a semiconductor light emitting device and a stacked structure body.

### BACKGROUND

Recently, attention has been paid to a semiconductor light emitting device having a top and bottom electrode structure in which the top and bottom of the device are sandwiched by electrodes. A typical example of such a semiconductor light emitting device is a LED (Light Emitting Diode). Manufacturing processes thereof are as follows. For example, a semiconductor stacked body including a light emitting layer is formed on a support substrate made of sapphire or the like. Subsequently, a conductive substrate is bonded to a major surface of the semiconductor stacked body on a side opposite to the support substrate. Thereafter, the support substrate is removed from the semiconductor stacked body. Electrodes are formed respectively on the surface of the semiconductor stacked body from which the support substrate has been removed, and on the conductive substrate.

With regard to the above-described processes, a laser lift-off technique has been disclosed as a technique for removing the support substrate from the semiconductor stacked body (for example, refer to JP-A 2009-099675 (Kokai)).

However, in the case where the support substrate is removed from the semiconductor stacked body by use of the laser lift-off technique, a bonding member interposed between the semiconductor stacked body and the conductive substrate is likely to be damaged by the laser irradiation. This causes problems that hinder the enhancement of the reliability of the semiconductor light emitting device and the manufacturing yields of the semiconductor light emitting device.

### BRIEF DESCRIPTION OF THE DRAWINGS

FIGS. 1A and 1B are schematic cross-sectional views of a main part of a semiconductor light emitting device;

FIGS. 2A to 4B are cross-sectional views of a main part of the semiconductor light emitting device in manufacturing processes;

FIGS. 5A to 7C are cross-sectional views of a main part of the semiconductor light emitting device in manufacturing processes of the first variation;

FIG. 8 is a cross-sectional view of a main part of the semiconductor light emitting device in manufacturing processes of a second variation; and

FIGS. 9A to 9C are cross-sectional views of a main part of the semiconductor light emitting device in manufacturing processes of a third variation.

### DETAILED DESCRIPTION

Exemplary embodiments will now be described with reference to the drawings. A semiconductor light emitting device manufactured in accordance with the embodiments will be described before describing processes of manufacturing the semiconductor light emitting device.

In general, according to one embodiment, a method is disclosed for manufacturing a semiconductor light emitting device. The method can include forming a plurality of semiconductor stacked bodies on a first major surface of a support substrate with a gap between two neighboring semiconductor stacked bodies. The semiconductor stacked bodies includes a first semiconductor layer, a second semiconductor layer, and a light emitting layer provided between the first semiconductor layer and the second semiconductor layer. The method can bond the plurality of semiconductor stacked bodies to one other support substrate with a bonding member. In addition, the method can remove the support substrate from the plurality of semiconductor stacked bodies by irradiating the plurality of semiconductor stacked bodies with a laser light from a second major surface of the support substrate on a side opposite to the first major substrate. The bonding member is not irradiated with the laser light.

According to another embodiment, a method is disclosed for manufacturing a semiconductor light emitting device. The method can include forming a plurality of semiconductor stacked bodies on a first major surface of a support substrate with a gap between two neighboring semiconductor stacked bodies. The semiconductor stacked bodies includes a first semiconductor layer, a second semiconductor layer, and a light emitting layer provided between the first semiconductor layer and the second semiconductor layer. In addition, the method can remove the support substrate from the plurality of semiconductor stacked bodies by irradiating the plurality of semiconductor stacked bodies with a laser light from a second major surface of the support substrate on a side opposite to the first main substrate. The support substrate and a support base supporting the plurality of semiconductor stacked bodies are not irradiated with the laser light.

According to still another embodiment, a stacked structure body includes a support substrate, semiconductor stacked bodies, and a light blocking film. The semiconductor stacked bodies are formed on a first major surface of the support substrate with a gap between two neighboring semiconductor stacked bodies. The semiconductor stacked bodies includes a first semiconductor layer, a second semiconductor layer, and a light emitting layer provided between the first semiconductor layer and the second semiconductor layer. The light blocking film is selectively provided on the support substrate. The light blocking film is configured to block a laser beam emitted from a side of the second major surface from entering the gap.

### First Embodiment

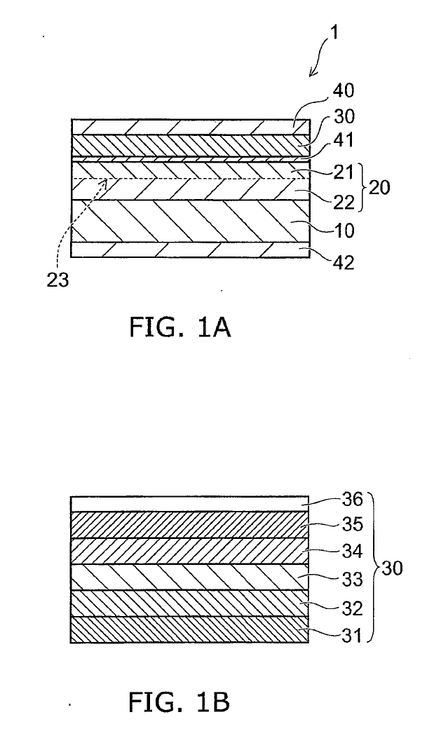

FIGS. 1A and 1B are schematic cross-sectional views of a main part of the semiconductor light emitting device.

A semiconductor light emitting device 1 includes a support substrate 10, a semiconductor stacked body 30, a bonding member 20 interposed between the support substrate 10 and the semiconductor stacked body 30.

The support substrate 10 is a substrate that supports the semiconductor light emitting device 1. The semiconductor stacked body 30 of a thin film type is formed above the support substrate 10. The semiconductor stacked body 30 is, for example, a LED (Light Emitting Diode). The bonding member 20 interposes between the support substrate 10 and the semiconductor stacked body 30.

A semiconductor substrate of silicon (Si), germanium (Ge) and the like is used as the support substrate 10, for example. Otherwise, metals such as copper (Cu) and molybdenum (Mo) may also be used as the support substrate 10. The semiconductor stacked body 30 includes a stacked body in which, for example, a p-type GaN layer 31, a p-type GaN guide layer 32, an active layer (light emitting layer) 33, an n-type GaN guide layer 34, an n-type GaN layer 35, and a GaN buffer layer 36 are provided in this order from the support substrate 10 side. The active layer 33 is interposed between a stacked body of n-type semiconductors and a stacked body of p-type semiconductors. The n-type GaN guide layer 34 and the n-type GaN layer 35 are regarded as a first semiconductor layer. The p-type GaN layer 31 and the p-type GaN guide layer 32 are regarded as a second semiconductor layer. The semiconductor stacked body 30 includes the active layer (light emitting layer) 33, which is provided between the first semiconductor layer and the second semiconductor layer. As an example, the active layer 33 is configured with an In_{0.15}Ga_{0.85}N/In_{0.02}Ga_{0.98}N-MQW (Multi-quantum Well) structure or the like, and for example, blue light, violet light, and the like are emitted from the active layer 33.

As an n-side electrode, an electrode film 40 is formed on at least a part of the major surface of the semiconductor stacked body 30 on the GaN buffer layer 36 side. The electrode film 40 is an n-side main electrode of the semiconductor light emitting device 1. For example, a conductive film such as ITO (indium tin oxide), a metal film or the like is used as the electrode film 40. Otherwise, a stacked body in which AuGe/Mo/Au are stacked in this order from the semiconductor stacked body 30 side, a stacked body in which Ti/Pt/Au are stacked in this order from the semiconductor stacked body 30 side, a stacked body in which Cr/Ti/Au are stacked in this order from the semiconductor stacked body 30 side, and the like are used as the electrode film 40. In the case where ITO or a transparent metal film is used as the electrode film 40, light emitted from the active layer 33 can be extracted from the electrode film 40 side.

As a p-side electrode, an electrode film 41 is formed on at least a part of the major surface of the semiconductor stacked body 30 on the p-type GaN layer 31 side. For example, a stacked body in which Ni/Ag are stacked in this order from the p-type GaN layer 31 side is used as the electrode film 41.

The bonding member 20 has a structure in which a bonding member 21 beforehand bonded to the electrode film 41 and a bonding member 22 beforehand bonded to the support substrate 10 are connected to each other in a position 23.

A single-layered film made of at least one metal selected from a group consisting of Ti, Pt, Au and the like is used as the bonding member 21, for example. Alternatively, a stacked body formed by stacking single-layered films respectively made of Ti, Pt, Au, and the like is used as the bonding member 21, for example.

A single-layered film made of at least one selected from a group consisting of AuSn, NiSn, Au, Pt, Ti, Si and the like or a single-layered film made of AuSn, NiSn or the like is used as the bonding member 22, for example. Alternatively, a stacked body formed by stacking single-layered films respectively made of AuSn, NiSn, Au, Pt, Ti, Si, and the like is used as the bonding member 22.

In the case where each of the bonding members 21 and 22 is formed from a stacked body, the stacking order of the constituent layers is arbitrarily. All the combinations of the stacking order are included in this embodiment.

In addition, an electrode film 42, which is a p-side main electrode, is connected to the support substrate 10. A stacked body in which, for example, Si/Ti/Pt/Au are stacked in this order from the support substrate 10 side is used as the electrode film 42. As described above, the semiconductor light emitting device 1 is a light emitting device having a top and bottom electrode structure (or a vertical structure).

Next, a method of manufacturing the semiconductor light emitting device 1 will be described.

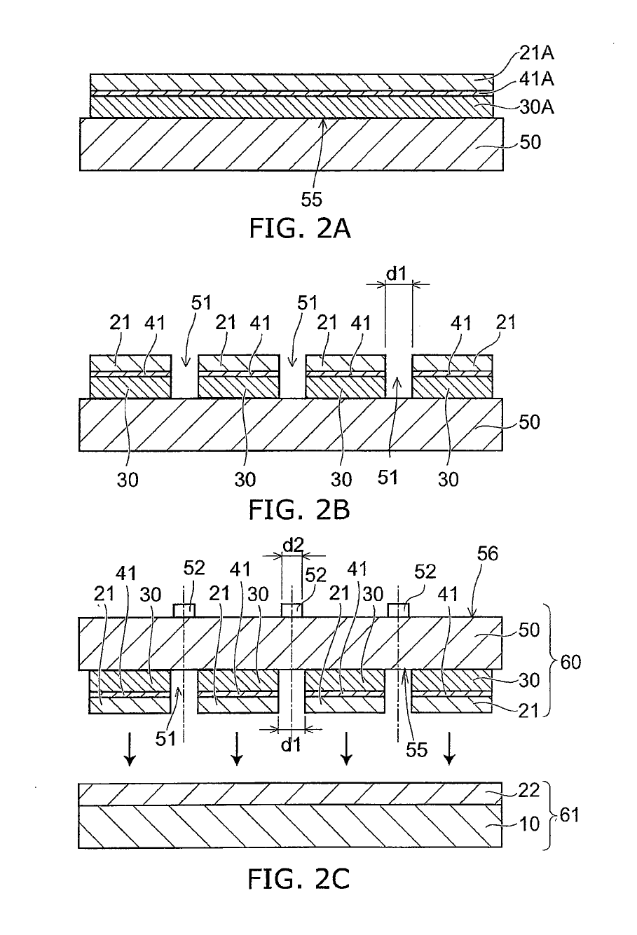

FIG. 2A to FIG. 4B are cross-sectional views of a main part of the semiconductor light emitting device 1 in manufacturing processes.

In this embodiment, a substrate made of sapphire or the like is used as a growth substrate (a support substrate) 50 to grow the semiconductor stacked bodies 30.

First of all, as shown in FIG. 2A, a semiconductor stacked body 30A having a planer configuration is formed on a major surface 55 (a first major surface) of the growth substrate 50. The thickness of the growth substrate 50 is, for example, 300 μm to 500 μm. The semiconductor stacked body 30A is formed on the growth substrate 50 by epitaxial growth. The semiconductor stacked body 30A has the same stacked structure as the semiconductor stacked body 30 described above.

Subsequently, an electrode film 41A, which has the same components as the electrode film 41 described above, is formed on the semiconductor stacked body 30A. Further, a bonding member 21A, which has the same components as the bonding member 21 described above, is formed on the electrode film 41A. The electrode film 41A and the bonding member 21A are formed, for example, by sputtering, CVD (chemical vapor deposition), and the like.

Thereafter, the semiconductor stacked body 30A, the electrode film 41A, and the bonding member 21A are etched to form gaps 51 as shown in FIG. 2B. Here, the gaps 51 are separation grooves, which are formed by dividing the semiconductor stacked body 30A, the electrode film 41A and the bonding member 21A on the growth substrate 50. The etching may be achieved by dry-etching or by wet-etching. Also, the gaps 51 may be formed by laser processing. Thereby, multiple stacked bodies including the semiconductor stacked body 30, the electrode film 41 and the bonding member 21 are selectively formed on the major surface 55 of the growth substrate 50 with the gap 51 between each two neighboring stacked bodies. In the case where the width of the gap 51 in a direction parallel to the major surface of the growth substrate 50 is taken as d1, d1 is in a range of several micrometers to several millimeters.

Subsequently, as shown in FIG. 2C, a light blocking film 52 (first light blocking film) is patterned on the growth substrate 50. In this embodiment, the light blocking film 52 is selectively formed in a portion of a major surface 56 of the growth substrate 50 on a side opposite to a portion where the gap 51 is provided. The light blocking film 52 is formed, for example, by photolithography in a way that the center line of the light blocking film 52 approximately coincides with the center line of the gap 51. Here, in the case where d2 is the width of the light blocking film 52 in a direction parallel to the major surface of the growth substrate 50, the light blocking film 52 is formed in a way that d2 is slightly smaller than d1.

At this point, a stacked structure body 60 is prepared which includes: the growth substrate 50; the semiconductor stacked bodies 30 selectively formed on the growth substrate 50 with the gap 51 between each two neighboring semiconductor stacked bodies 30; the light blocking film 52 formed in a portion of the major surface of the growth substrate 50 on a side opposite to a portion where the gap 51 is provided; and the bonding members 21.

A light reflecting film that reflects a laser beam or a coating film that absorbs a laser beam is used as the light blocking film 52, for example.

For example, at least one element selected from a group consisting of titanium (Ti), nickel (Ni), palladium (Pd), platinum (Pt), rhodium (Rh), tungsten (W), gold (Au), aluminum (Al) and carbon (C) is used as the material of the light blocking film 52. Alternatively, an alloy containing two or more of these elements is used as the material of the light blocking film 52.

In addition, for example, a gold-tin (AuSn) alloy, aluminum nitride (AlN), titanium nitride (TiN) or tungsten nitride (WN) is used as the material of the light blocking film 52.

Further, for example, an gold-tin (AuSn) alloy containing at least one element selected from a group consisting of titanium (Ti), nickel (Ni), palladium (Pd), platinum (Pt), rhodium (Rh), tungsten (W), gold (Au), aluminum (Al) and carbon (C) is used as the material of the light blocking film 52.

Further, for example, aluminum nitride (AlN) containing at least one element selected from a group consisting of titanium (Ti), nickel (Ni), palladium (Pd), platinum (Pt), rhodium (Rh), tungsten (W), gold (Au), aluminum (Al) and carbon (C) is used as the material of the light blocking film 52.

Further, a resist, any other organic film or the like is used as the material of the light blocking film 52. Alternatively, a dielectric multilayered film that reflects a laser beam may be used as the material of the light blocking film 52. Oxides such as silicon oxide (SiO₂), alumina (Al₂O₃), and titanium oxide (TiO₂) fall within the scope of the dielectric film.

It is desirable that a substance which has a suitable adhesiveness to the growth substrate 50 is selected as the above-illustrated materials of the light blocking film 52. Furthermore, it is desirable for the above-illustrated materials to have a melting point such that a substance does not melt even when the substance is irradiated with a laser light described below.

Note that the light blocking film 52 may be formed on the growth substrate 50 before forming the gaps 51. Particularly in a case where the light blocking film 52 is a nitride film or an oxide film, the thermal tolerance becomes high. In this case, the light blocking film 52 may be formed on the growth substrate 50 before forming the semiconductor stacked body 30A on the growth substrate 50.

Subsequently, as shown in FIG. 2C, the stacked structure body 60 including the growth substrate 50, the semiconductor stacked bodies 30, the electrode films 41 and the bonding members 21 is opposed to a stacked structure body 61 including the support substrate 10 (the other support substrate) and the bonding member 22.

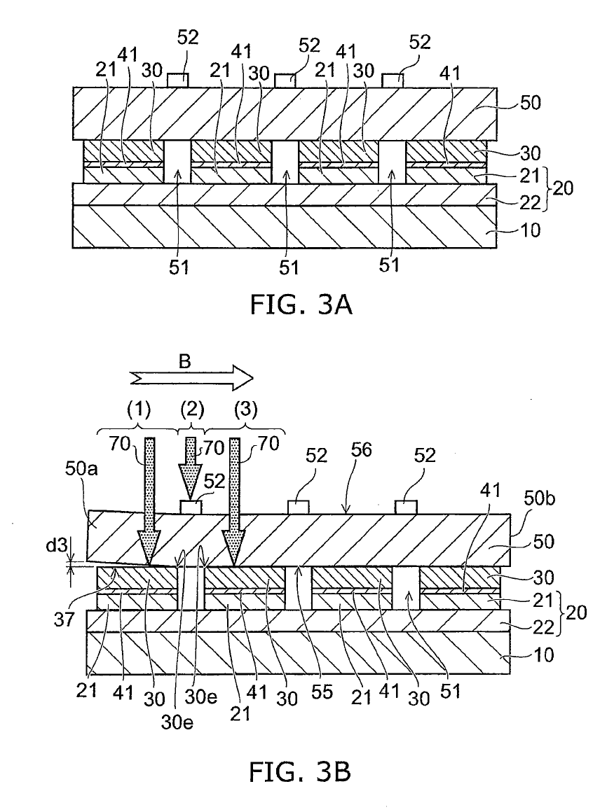

After that, the stacked structure body 60 is faced down and lowered in a direction indicated by arrows. Thus, as shown in FIG. 3A, the bonding members 21 and the bonding member 22 are brought into contact with each other. Subsequently, a heating treatment or an ultrasonic treatment is performed to cause mutual diffusion in the bonding members 21 and the bonding member 22. This mutual diffusion makes the bonding members 21 and the bonding member 22 bonded together. Thereby, the above-described bonding member 20 is formed, and each of the multiple semiconductor stacked bodies 30 are bonded to the support substrate 10 by the bonding member 20. The support substrate 10 also functions, for example, as a heat sink as well. Note that the electrode films 41 interpose between the semiconductor stacked bodies 30 and the bonding member 20.

Subsequently, as shown in FIG. 3B, the growth substrate 50 is removed from the semiconductor stacked bodies 30 by a laser lift-off (LLO) process. For example, an ArF laser (wavelength: 193 nm), a KrF laser (wavelength: 248 nm), a XeCl laser (wavelength: 308 nm) or a XeF laser (wavelength: 353 nm) is used as a laser beam 70.

In the laser lift-off process according to this embodiment, for example, the laser beam 70 enters the growth substrate 50 almost perpendicularly from the major surface 56 (the second major surface) on a side opposite to the major surface 55 of the growth substrate 50, and is scanned in a direction from an end 50a of the growth substrate 50 to the other end 50b of the growth substrate 50 (in a direction indicated by an arrow B).

For example, in an area (1), the laser beam 70 penetrates the growth substrate 50 and reaches the semiconductor stacked body 30. At this time, the semiconductor stacked body 30 absorbs the energy of the laser beam 70 at the interface between the growth substrate 50 and the semiconductor stacked body 30. A GaN component in the semiconductor stacked body 30 is thereby thermally decomposed, for example, in accordance with the following chemical equation.

GaN→Ga+(½)N_{2↑}

As a result, the growth substrate 50 is removed from the semiconductor stacked body 30. FIG. 3B illustrates a state in which the major surface 55 of the growth substrate 50 and the major surface 37 of the semiconductor stacked body 30 are separated from each other by a distance d3.

Particularly because the width of the light blocking film 52 is narrower than the width of the gap 51, end portions 30e of the major surface 37 of the semiconductor stacked body 30 are irradiated with the laser beam 70. For this reason, the laser irradiation weakens the adhesion between an overall area of the major surface 37 of the semiconductor stacked body 30 and the growth substrate 50. Accordingly, the growth substrate 50 is securely removed from the semiconductor stacked body 30. Note that the power of the laser beam 70 is 0.5 J/cm² to 1.0 J/cm².

Note that the thermal decomposition of the GaN component produces a nitrogen (N₂) gas between the growth substrate 50 and the semiconductor stacked body 30. This nitrogen (N₂) gas can enter the gap 51 because the gap 51 is made between the semiconductor stacked body 30 and the neighboring semiconductor stacked body 30. As a result, a phenomenon in which the nitrogen (N₂) gas remains between the growth substrate 50 and the semiconductor stacked body 30 can be suppressed.

If this phenomenon occurs, for example, the growth substrate 50 is distorted, and stress is accordingly applied to the semiconductor stacked body 30. Consequently, the semiconductor stacked body 30 is likely to crack and chip. In this embodiment, by forming the gap 51, the stress described above is suppressed and damages (cracks and chips) of the semiconductor stacked body 30 are suppressed.

Next, in the area (2), because the light blocking film 52 exists, the laser beam 70 is blocked by the light blocking film 52. Thereby, the laser beam 70 is blocked from entering the gap 51. As a result, the laser beam 70 does not reach the bonding member 22. Accordingly, the bonding member 22 is not damaged by the laser beam irradiation. Then, in an area (3), the laser beam 70 again penetrates the growth substrate 50 and reaches the semiconductor stacked body 30. Like in the area (1), the growth substrate 50 is removed from the semiconductor stacked body 30 in this area. As described above, in steps (1) to (3), the multiple semiconductor stacked bodies 30 are removed from the growth substrate 50 by irradiating the multiple semiconductor stacked bodies 30 with the laser beam 70, but not irradiating the bonding member 22 with the laser beam 70. Such a laser scan enables the growth substrate 50 to be removed from all the multiple semiconductor stacked bodies 30.

Moreover, in this embodiment, a rise shot (a first shot) of the laser beam 70 can be adjusted in a portion of this light blocking film 52. Thereby, there are advantages of suppressing, for example, an unstable portion of the laser beam 70 during the rise time, improper LLO due to power shortage, damage on GaN due to excessively high power, and the like.

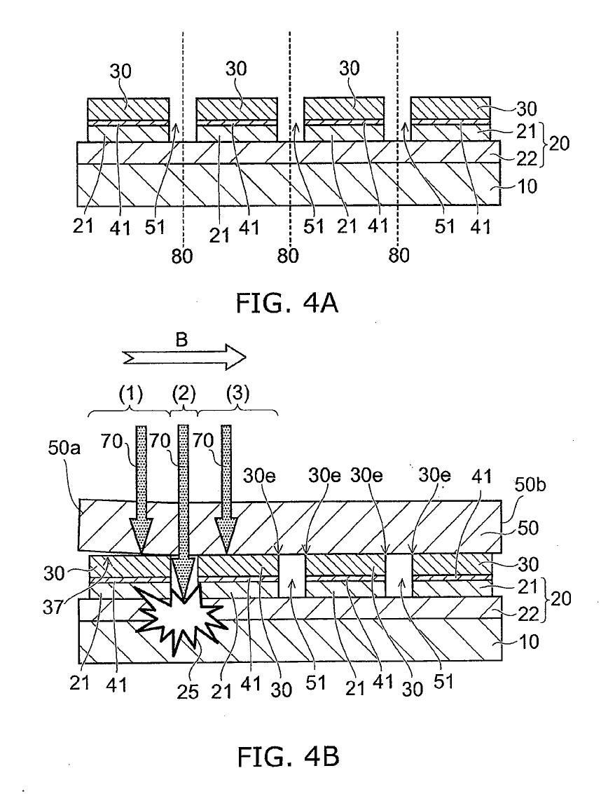

Next, as shown in FIG. 4A, the support substrate 10 and the bonding member 22 are cut along dicing lines 80. After that, the electrode films 40 and 42 described above are formed. Consequently, the semiconductor light emitting device 1 shown in FIGS. 1A and 1B is produced.

In contrast to this, a comparative example is shown in FIG. 4B. FIG. 4B shows an application of a laser lift-off process in a state in which no light blocking film 52 exists.

For example, in the area (1), the laser beam 70 penetrates the growth substrate 50 and reaches the semiconductor stacked body 30. At this time, the semiconductor stacked body 30 absorbs the energy of the laser beam 70 at the interface between the growth substrate 50 and the semiconductor stacked body 30. Thereby, the GaN component in the semiconductor stacked body 30 is thermally decomposed. As a result, the adhesion between the growth substrate 50 and the semiconductor stacked body 30 becomes weak, and the growth substrate 50 is accordingly removed from the semiconductor stacked body 30. A phenomenon which has occurred up to this is the same as the above-described phenomenon.

In the area (2), however, the laser beam 70 penetrates the growth substrate 50 and reaches the bonding member 22 because no light blocking film 52 exists. There is a case where the bonding member 22 absorbs the energy of the laser beam 70 and be melted if the bonding member 22 is irradiated with (is directly hit by) the laser beam 70. In other words, the bonding member 22 receives damage 25 as a result of the laser irradiation. In addition, if the bonding member 22 is irradiated with the laser beam 70, the temperature of the bonding member 22 rises and stress is applied to the bonding member 22. Thereby, the bonding member 22 itself may receive damages (cracks and chips) and the bonding member 22 may be peeled off from the bonding member 21 or the support substrate 10. Further, if the stress is transmitted to the semiconductor stacked body 30, the semiconductor stacked body 30 is likely to receive damage.

The damage and separation are likely to further progress depending on the wet-treatment process and heat history after the dicing process. This decreases the reliability and manufacturing yields of the semiconductor light emitting device.

In contrast to this, in this embodiment, the light blocking film 52 described above is provided, and accordingly the damage and separation of the bonding member 22 as well as the damage of the semiconductor stacked body 30 are suppressed. Thus, the highly-reliable semiconductor light emitting device 1 is produced. Further, the manufacturing yields of the semiconductor light emitting device 1 are enhanced.

Next, variations of the method of manufacturing the semiconductor light emitting device 1 will be described. Note that, in the following descriptions, members which are the same as the foregoing members will be denoted by the same reference signs; and descriptions for such members will be omitted as appropriate.

### Second Embodiment

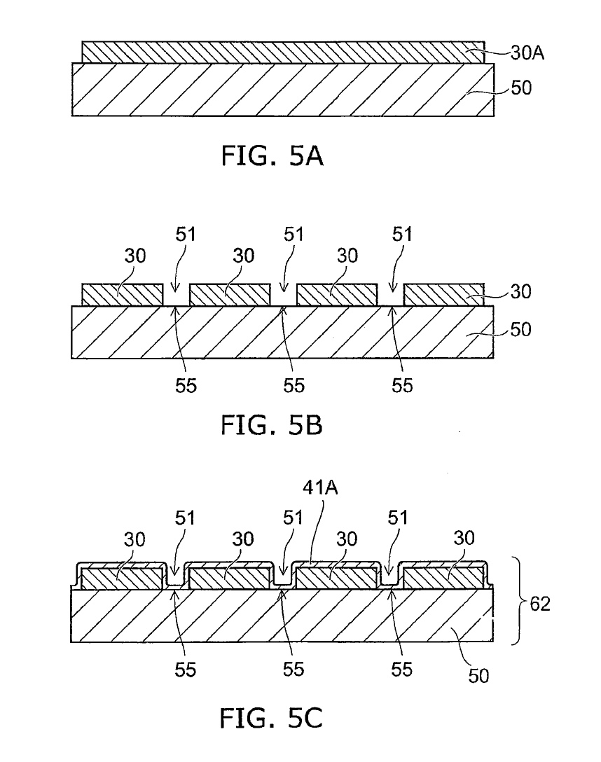

FIG. 5A to FIG. 7C are cross-sectional views of a main part of the semiconductor light emitting device 1 in manufacturing processes of a first variation.

First of all, as shown in FIG. 5A, the semiconductor stacked body 30A is formed on the major surface of the growth substrate 50. The semiconductor stacked body 30A is formed on the growth substrate 50 by epitaxial growth.

Subsequently, the semiconductor stacked body 30A is etched to form the gaps 51 as shown in FIG. 5B. The etching process may be achieved by dry etching or wet etching. Also, the gaps 51 may be formed by laser processing. Thereby, the semiconductor stacked bodies 30 are selectively formed on the major surface 55 of the growth substrate 50 with the gap 51 between each two neighboring semiconductor stacked bodies 30.

Thereafter, as show in FIG. 5C, the electrode film 41A whose component is the same as that of the electrode film 41 is formed on the semiconductor stacked bodies 30 and on the major surface 55 of the growth substrate 50 in portions where the gaps 51 are provided. The electrode film 41A is formed, for example, by sputtering, CVD or the like. In this embodiment, the electrode film 41A formed on the major surface 55 in the portions where the gaps 51 are provided functions as a light blocking film (second light blocking film). This will be described later.

At this point, a stacked structure body 62 is prepared which includes: the growth substrate 50; the semiconductor stacked bodies 30 selectively formed on the growth substrate 50 with the gap 51 between each two neighboring semiconductor stacked bodies 30; and the light blocking film (the electrode film 41A) formed on the major surface 55 of the growth substrate 50 in the portions where the respective gaps 51 are provided.

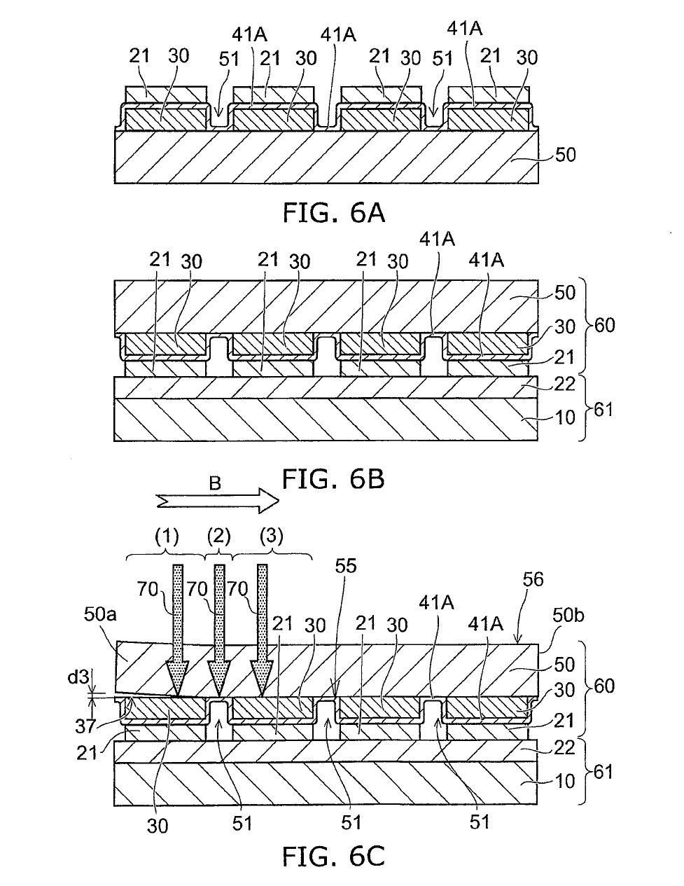

Next, as shown in FIG. 6A, the bonding members 21 are formed on the semiconductor stacked bodies 30 via the electrode film 41A. The bonding members 21 are selectively formed, for example, by a publicly-known lift-off process using a resist and the like. In addition, the film formation of the bonding members 21 is performed, for example, by sputtering, CVD or the like.

After that, as shown in FIG. 6B, the stacked structure body 60 including the growth substrate 50, the semiconductor stacked bodies 30, the electrode film 41A and the bonding members 21 is brought into contact with the stacked structure body 61 including the support substrate 10 and the bonding member 22. Subsequently, the stacked structure body 60 and the stacked structure body 61 are subjected to a heating treatment. Thereby, the bonding members 21 and the bonding member 22 are bonded to each other due to the mutual diffusion of the bonding members 21 and the bonding member 22.

Thereafter, as shown in FIG. 6C, a laser lift-off process is applied, and the growth substrate 50 is removed from the semiconductor stacked bodies 30.

Like in the first embodiment, in the laser lift-off process according to this embodiment, the laser beam 70 enters the growth substrate 50 almost perpendicularly and is scanned in a direction from the end 50a of the growth substrate 50 to the other end 50b of the growth substrate 50 (in a direction indicated by an arrow B).

For example, in the area (1), the laser beam 70 penetrates the growth substrate 50 and reaches the semiconductor stacked body 30. At this time, the semiconductor stacked body 30 absorbs the energy of the laser beam 70 at the interface between the growth substrate 50 and the semiconductor stacked body 30. Thereby, the GaN component in the semiconductor stacked body 30 is thermally decomposed. As a result, the growth substrate 50 is removed from the semiconductor stacked body 30.

Next, in the area (2), the laser beam 70 is blocked by the electrode film 41A. To put it specifically, the electrode film 41A provided in the gap 51 functions as a light blocking film. Accordingly, the laser beam 70 is blocked from entering the gap 51. As a result, the laser beam 70 does not reach the bonding member 22. Accordingly, the bonding member 22 receives no damage. Then, in the area (3), the laser beam 70 again penetrates the growth substrate 50 and reaches the semiconductor stacked body 30. Like in the area (1), the growth substrate 50 is removed from the semiconductor stacked body 30 in this area. Such a laser scan enables the growth substrate 50 to be removed from all the semiconductor stacked bodies 30.

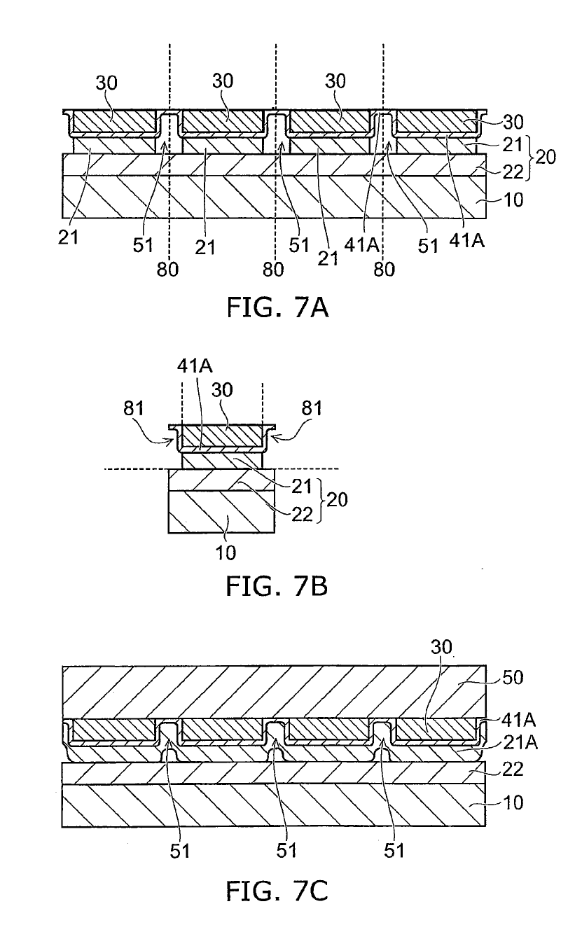

Subsequently, as shown in FIG. 7A, the support substrate 10 and the bonding member 22 are cut along the dicing lines 80. Thereafter, as shown in FIG. 7B, portions of the electrode film 41A attaching to the sidewalls of the semiconductor stacked bodies 30 are removed as unnecessary portions 81, for example, by wet etching. Afterward, the electrode films 40 and 42 are formed. Thereby, the semiconductor light emitting device 1 shown in FIGS. 1A and 1B is produced.

In this embodiment, the electrode film 41A is used as a light blocking film, and accordingly the damage and separation of the bonding member 22 as well as the damage of the semiconductor stacked bodies 30 are suppressed. Thereby, the highly-reliable to semiconductor light emitting device 1 is formed. Moreover, the manufacturing yields of the semiconductor light emitting device 1 are further enhanced.

Note that, besides the electrode film 41A, the bonding member 21A may also be used as a light blocking film in this embodiment. For example, FIG. 7C illustrates a state in which the bonding member 21A is formed besides the electrode film 41A in the gaps 51. In the case where the light blocking film is formed from such electrode film 41A and bonding member 21A, the thickness of the light blocking film increases more than the light blocking film formed from the electrode film 41A alone, and the light blocking effect further increases. Accordingly, a more highly-reliable semiconductor light emitting device 1 is produced. In addition, the manufacturing yields of the semiconductor light emitting device 1 are further enhanced.

### Third Embodiment

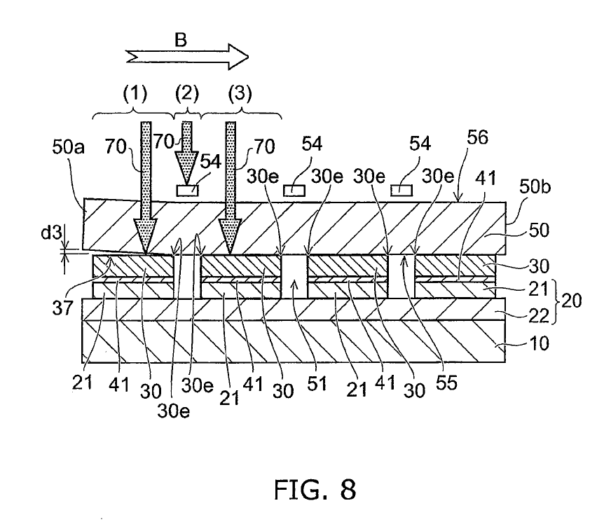

FIG. 8 is a cross-sectional view of a main part of the semiconductor light emitting device 1 in manufacturing processes of a second variation.

In this embodiment, a mask member is used for blocking the laser beam instead of the light blocking film 52. For example, light blocking masks 54 are placed above the major surface 56 of the growth substrate 50 on a side opposite to the portions where the gaps 51 are provided. The light blocking masks 54 are selectively provided with the respective light blocking bodies in order to block light from entering the gaps 51. When a laser lift-off process is applied via such a light block mask 54, for example, in the area (1), the laser beam 70 penetrates the growth substrate 50 and reaches the semiconductor stacked body 30. At this time, the semiconductor stacked body 30 absorbs the energy of the laser beam 70 at the interface between the growth substrate 50 and the semiconductor stacked body 30. Thereby, the GaN component in the semiconductor stacked body 30 is thermally decomposed. As a result, the adhesion between the growth substrate 50 and the semiconductor stacked body 30 becomes weak. Accordingly, the growth substrate 50 is removed from the semiconductor stacked body 30.

Subsequently, in the area (2), the laser beam 70 is blocked by the light blocking mask 54. Accordingly, the laser beam 70 is blocked from entering the gap 51. As a result, the laser beam 70 does not reach the bonding member 22. Accordingly, the bonding member 22 receives no damage. Then, in the area (3), the laser beam 70 again penetrates the growth substrate 50 and reaches the semiconductor stacked body 30. Like in the area (1), the growth substrate 50 is removed from the semiconductor stacked body 30 in this area. Such a laser scan enables the growth substrate 50 to be removed from all the semiconductor stacked bodies 30.

In this embodiment, the light blocking mask 54 is used to suppress damage of the bonding member 22. Thereby, the highly-reliable semiconductor light emitting device 1 is formed. In addition, the manufacturing yields of the semiconductor light emitting device 1 are further enhanced.

### Fourth Embodiment

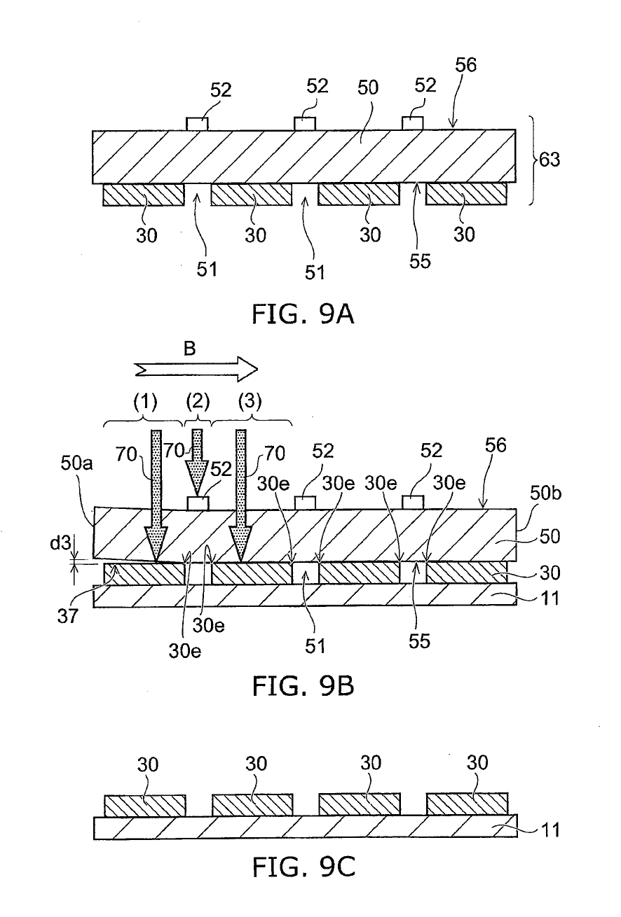

FIGS. 9A to 9C are cross-sectional views of a main part of the semiconductor light emitting device 1 in manufacturing processes of a third variation.

First of all, as shown in FIG. 9A, a stacked structure body 63 including the growth substrate 50, the multiple semiconductor stacked bodies 30, and the light blocking films 52 is prepared. The semiconductor stacked bodies 30 are selectively formed on the major surface 55 of the growth substrate 50 with the gap 51 between each two neighboring semiconductor stacked bodies 30. Each of the light blocking films 52 is formed on the major surface 56 of the growth substrate 50 on a side opposite to a portion where the gap 51 is provided. The semiconductor stacked bodies 30 are selectively formed on the growth substrate 50 with the gap 51 between each two neighboring semiconductor stacked bodies 30.

Subsequently, as shown in FIG. 9B, the growth substrate 50 and the multiple semiconductor stacked bodies 30 are placed on a support base 11. The support base 11 is a support base that supports the growth substrate 50 and the multiple semiconductor stacked bodies 30. The support base 11 may be a table plate of the laser processing apparatus or a stem member for supporting the semiconductor stacked bodies 30.

When a laser lift-off process is applied in this condition, for example, in the area (1), the laser beam 70 penetrates the growth substrate 50 and reaches the semiconductor stacked body 30. At this time, the semiconductor stacked body 30 absorbs the energy of the laser beam 70 at the interface between the growth substrate 50 and the semiconductor stacked body 30. Thereby, the GaN component in the semiconductor stacked body 30 is thermally decomposed. As a result, the adhesion between the growth substrate 50 and the semiconductor stacked body 30 becomes weak. Accordingly, the growth substrate 50 is removed from the semiconductor stacked body 30.

Subsequently, in the area (2), the laser beam 70 is blocked by the light blocking film 52. As a result, the laser beam 70 does not reach the support base 11. Accordingly, the support base 11 receives no damage. Then, in the area (3), the laser beam 70 again penetrates the growth substrate 50 and reaches the semiconductor stacked body 30. Like in the area (1), the growth substrate 50 is removed from the semiconductor stacked body 30 in this area. Such a laser scan enables the growth substrate 50 to be removed from all the semiconductor stacked bodies 30 (see FIG. 9C).

As described above, in this embodiment, damage on the support base 11 supporting the semiconductor stacked bodies 30 is suppressed. Thereby, the manufacturing yields of the chip-shaped semiconductor stacked bodies 30 are further enhanced.

The foregoing descriptions have been provided for the embodiments while referring to the concrete examples. However, the embodiments are not limited to these concrete examples. Specifically, any of these concrete examples added with an appropriate design change by those skilled in the art shall be included in the scope of the embodiments, as long as it has any of the characteristics of the embodiments. For example, components and their respective placements, materials, conditions, shapes, sizes and the like are not limited to those illustrated in the foregoing concrete examples, and can be changed whenever deemed necessary. For example, an opt-electronic integrated circuit, which is integrated on the same support substrate 10 and capable of processing light signals emitted from the semiconductor light emitting devices 1, is also included in the embodiments.

Moreover, the components included in the above-described embodiments can be combined together as long as the combination is technically achievable. Any such combination is also included in the scope of embodiments as long as the combination has any of the characteristics of the embodiments.

Those skilled in the art could conceive various modifications and alterations in the scope of the spirit of the embodiments. It shall be understood that such modifications and alterations belong to the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1. A method of manufacturing a semiconductor light emitting device, comprising:
forming a plurality of semiconductor stacked bodies on a first major surface of a support substrate with a gap between two neighboring semiconductor stacked bodies, the semiconductor stacked bodies including a first semiconductor layer, a second semiconductor layer, and a light emitting layer provided between the first semiconductor layer and the second semiconductor layer;
bonding the plurality of semiconductor stacked bodies to one other support substrate with a bonding member; and
removing the support substrate from the plurality of semiconductor stacked bodies by irradiating the plurality of semiconductor stacked bodies with a laser light from a second major surface of the support substrate on a side opposite to the first major substrate, the bonding member being not irradiated with the laser light.

2. The method according to claim 1, wherein
the bonding member is formed on the semiconductor stacked bodies.

3. The method according to claim 1, wherein
in the removing the support substrate, the laser beam is blocked from entering the gap by a first light blocking film provided on the second major surface of the support substrate.

4. The method according to claim 1, wherein
in the removing the support substrate, the laser beam is blocked from entering the gap by a second light blocking film provided on the first major surface of the support substrate.

5. The method according to claim 4, wherein
the second light blocking film is formed on the semiconductor stacked bodies and on the first major surface of the support substrate between two neighboring semiconductor stacked bodies.

6. The method according to claim 4, wherein
the plurality of semiconductor stacked bodies is bonded to the one other support substrate via the second light blocking film with the bonding member.

7. The method according to claim 1, wherein
in the removing the support substrate, a light blocking mask is placed above the second major surface of the support substrate, and the laser beam is blocked from entering the gap by the light blocking mask.

8. A method of manufacturing a semiconductor light emitting device, comprising:
forming a plurality of semiconductor stacked bodies on a first major surface of a support substrate with a gap between two neighboring semiconductor stacked bodies, the semiconductor stacked bodies including a first semiconductor layer, a second semiconductor layer, and a light emitting layer provided between the first semiconductor layer and the second semiconductor layer; and
removing the support substrate from the plurality of semiconductor stacked bodies by irradiating the plurality of semiconductor stacked bodies with a laser light from a second major surface of the support substrate on a side opposite to the first main substrate, the support substrate and a support base supporting the plurality of semiconductor stacked bodies being not irradiated with the laser light.

9. The method according to claim 8, wherein
a bonding member is formed on the semiconductor stacked bodies.

10. The method according to claim 8, wherein
in the removing the support substrate, the laser beam is blocked from entering the gap by a first light blocking film provided on the second major surface of the support substrate.

11. The method according to claim 8, wherein
in the removing the support substrate, the laser beam is blocked from entering the gap by a second light blocking film provided on the first major surface of the support substrate.

12. The method according to claim 11, wherein
the second light blocking film is formed on the semiconductor stacked bodies and on the first major surface of the support substrate between two neighboring semiconductor stacked bodies.

13. The method according to claim 11, wherein
the plurality of semiconductor stacked bodies is bonded to the one other support substrate via the second light blocking film with the bonding member.

14. The method according to claim 8, wherein
in the removing the support substrate, a light blocking mask is placed above the second major surface of the support substrate, and the laser beam is blocked from entering the gap by the light blocking mask.

15. A stacked structure body comprising:
a support substrate;
semiconductor stacked bodies formed on a first major surface of the support substrate with a gap between two neighboring semiconductor stacked bodies, the semiconductor stacked bodies including a first semiconductor layer, a second semiconductor layer, and a light emitting layer provided between the first semiconductor layer and the second semiconductor layer; and
a light blocking film provided on the support substrate, the light blocking film configured to block a laser beam emitted from a side of a second major surface from entering the gap.

16. The body according to claim 15, wherein
the light blocking film is provided on the second major surface of the support substrate on a side opposite to the first major surface of the support substrate.

17. The body according to claim 15, wherein
the light blocking film is provided on the first major surface.

18. The body according to claim 17, wherein
the light blocking film is provided on the semiconductor stacked bodies and on the first major surface of the support substrate between two neighboring semiconductor stacked bodies.
